(19) United States
(12) Patent Application Publication
(10) Pub. No.: US 2018/0287599 A1
(43) Pub. Date: Oct. 4, 2018

(54) CONTROLLER, CONTROL METHOD, AD CONVERTER, AND AD CONVERSION METHOD

(71) Applicant: SONY SEMICONDUCTOR SOLUTIONS CORPORATION, Kanagawa (JP)

(72) Inventors: Kazutoshi TOMITA, Kanagawa (JP); Atsumi NIWA, Kanagawa (JP)

(21) Appl. No.: 15/524,377

(22) PCT Filed: Oct. 29, 2015
(86) PCT No.: PCT/JP2015/080485

§ 371 Date: May 4, 2017

(30) Foreign Application Priority Data
Nov. 12, 2014 (JP) 2014-229711

(51) Int. Cl. H03K 17/04; H03M 1/56; H03M 1/00; G05F 3/02; H04N 5/378

(52) U.S. Cl. CPC H03K 17/04; H03M 1/56; H04N 5/378; G05F 3/02; H03M 1/002

(57) ABSTRACT

The present technology relates to a controller, a control method, an AD converter, and an AD conversion method by which settling can be improved. The controller includes: a first current source that generates an output signal corresponding to an input signal; a second current source that supplies a current to charge a predetermined capacitance; and a control unit that controls the current supplied from the second current source to the predetermined capacitance, where the first current source and the second current source are each formed of a transistor. The controller further includes a supply unit that supplies a current flowing to the first current source and the second current source, where the current flowing to the first current source and the second current source is proportional to a current flowing in the supply unit. The present technology can be applied to an AD converter included in an imaging apparatus.

### TECHNICAL FIELD

The present technology relates to a controller, a control method, an AD converter, and an AD conversion method. In particular, the present technology relates to a controller, a control method, an AD converter, and an AD conversion method by which settling time can be reduced.

### BACKGROUND ART

An imaging apparatus uses an analog/digital converter (AD converter) to perform processing of converting an analog pixel signal read from a pixel into digital data. Where all kinds of AD converters are used in the imaging apparatus, a so-called single-slope integrating (or ramp signal comparing) AD converter is used in many cases.

The single-slope integrating AD converter that performs an AD conversion by comparing a reference signal includes a reference signal generation unit that generates a reference signal called a ramp wave which changes gradually from a predetermined initial voltage with a predetermined slope, a comparator that compares the reference signal with a pixel signal, and a counter that counts the time it takes for a magnitude relationship between the reference signal and the pixel signal to be reversed from the start of output of the reference signal by the reference signal generation unit (or the output of the predetermined initial value).

In order for such an AD converter to start a new AD conversion after completing a previous AD conversion, the converter requires time (so-called settling time) to restore the reference signal to the initial value. Although it is preferable to reduce the settling time in order to speed up AD conversion processing, the AD conversion may not be performed properly when the settling time is reduced without careful consideration to allow the new AD conversion to start before the reference signal is fully restored to the initial value.

Patent Document 1 proposes a current driver for reducing the settling time. The current driver according to Patent Document 1 includes a current source that supplies a data current corresponding to a data signal, a differential circuit that generates a differential voltage value of a data line, and a boost current source that supplies a boost current corresponding to the differential value to the data line.

It is proposed for the current driver to use the differential circuit and the boost current source in order to improve settling. Where β is a capacitor holding the data and Cp is a parasitic capacitance, the data current from the current source is partly consumed for charging the parasitic capacitance Cp so that the charging time of the data holding capacitor β slows down.

Accordingly, it is proposed that the charging time, namely the settling, can be improved by calculating a differential value dV/dt of a voltage V of the data line in the differential circuit and supplying a current corresponding to a result of the calculation from the boost current source.

### CITATION LIST

### Patent Document

Patent Document 1: Japanese Patent Application Laid-Open No. 2009-128756

### SUMMARY OF THE INVENTION

### Problems to be Solved by the Invention

The differential circuit and the boost current source each use an amplifier in the Patent Document 1. The amplifier has high current consumption in general and thus possibly hinders a reduction in power consumption. Moreover, a gain of the amplifier can be increased to improve the precision of the boost current, in which case the increase in the gain can further increase the current consumption so that, from this perspective as well, the amplifier can possibly hinder the reduction in power consumption.

Moreover, in Patent Document 1, the differentiator includes a resistor and a capacitor. The resistor and the capacitor are generally large in area and thus not suitable for a circuit with a tight area requirement such as a column ADC circuit which is widely employed in an image sensor or the like. It is hard to apply the resistor and the capacitor to not just the image sensor but a circuit with a tight area requirement with which one wishes to benefit from the fine processing achieved in recent years.

The AD converter is widely used not just in the imaging apparatus. The reduction in the settling time leads to a reduction in processing time in the AD converter, whereby it is desired to further reduce the settling time.

Moreover, it is generally desired to achieve low power consumption in various devices so that the low power consumption is desirably achieved in the AD converter as well. A further reduction in size is also desired in some devices.

The present technology has been made in view of these circumstances, and can reduce the settling time as well as contribute to the reduction in the power consumption and size.

### Solutions to Problems

A controller according to an aspect of the present technology includes: a first current source that generates an output signal corresponding to an input signal; a second current source that supplies a current to charge a predetermined capacitance; and a control unit that controls the current supplied from the second current source to the predetermined capacitance, where the first current source and the second current source are each formed of a transistor.

The controller further includes a supply unit that supplies a current flowing to the first current source and the second current source, where the current flowing to the first current source and the second current source can be proportional to a current flowing in the supply unit.

The control unit is a switch that can be closed when settling time is to be reduced.

The supply unit can include a current source outputting a fixed current.

The supply unit can include a current source outputting a variable current.

The supply unit can include a first current supply unit that supplies a current to the first current source and a second current supply unit that supplies a current to the second current source.

The first current supply unit can include a first transistor and a first current generating source, while the second current supply unit can include a second transistor and a second current generating source.

The first current generating source and the second current generating source can be provided independently.

The first current generating source and the second current generating source can each be a current source outputting a variable current.

The first current generating source and the second current generating source can each be a current source outputting a fixed current.

In a control method of a controller according to an aspect of the present technology, the controller includes: a first current source that generates an output signal corresponding to an input signal; a second current source that supplies a current to charge a predetermined capacitance; and a control unit that controls the current supplied from the second current source to the predetermined capacitance, where the first current source and the second current source are each formed of a transistor, and the method includes a step in which the control unit performs control to supply, to the predetermined capacitance, the current from the second current source in addition to a current from the first current source when settling time is to be reduced.

An AD converter according to an aspect of the present technology includes: a comparator that compares a reference signal changing gradually from a predetermined initial voltage at a predetermined slope with a pixel signal; a counter that counts time for a magnitude relationship between the reference signal and the pixel signal to be reversed from a start of input of the reference signal; a first current source that uses the reference signal as an input signal and generates an output signal corresponding to the input signal; a second current source that supplies a current besides a current from the first current source until the reference signal equals a predetermined value; and a control unit that controls a flow of the current from the second current source, where the first current source and the second current source are each formed of a transistor.

In an AD conversion method of an AD converter according to an aspect of the present technology, the AD converter includes: a comparator that compares a reference signal changing gradually from a predetermined initial voltage at a predetermined slope with a pixel signal; a counter that counts time for a magnitude relationship between the reference signal and the pixel signal to be reversed from a start of input of the reference signal; a first current source that uses the reference signal as an input signal and generates an output signal corresponding to the input signal; a second current source that supplies a current besides a current from the first current source until the reference signal equals a predetermined value; and a control unit that controls a flow of the current from the second current source, where the first current source and the second current source are each formed of a transistor, and the method includes a step in which the control unit performs control to supply, to the predetermined capacitance, the current from the second current source in addition to the current from the first current source when settling time is to be reduced.

A controller and a control method according to an aspect of the present technology include: a first current source that generates an output signal corresponding to an input signal; a second current source that supplies a current to charge a predetermined capacitance; and a control unit that controls the current supplied from the second current source to the predetermined capacitance. The first current source and the second current source are each formed of the transistor so that the size and power consumption can be reduced. Moreover, the control unit performs control such that, in addition to the current from the first current source, the current from the second current source is supplied to the predetermined capacitance when the settling time is to be reduced.

### Effects of the Invention

According to an aspect of the present technology, the settling time as well as the power consumption and size can be reduced.

It should be noted that effects of the present technology are not limited to the effects described herein, and may include any of the effects described in the present disclosure.

### BRIEF DESCRIPTION OF DRAWINGS

FIG. 1 is a diagram illustrating the configuration of an embodiment of a controller to which the present technology is applied.

FIG. 2 is a diagram illustrating a specific configuration of a first controller.

FIGS. 3A and 3B are graphs provided to illustrate a reduction in settling time.

FIG. 4 is a diagram illustrating a specific configuration of a second controller.

FIG. 5 is a diagram provided to illustrate noise generated in the first controller.

FIG. 6 is a diagram provided to illustrate noise generated in the second controller.

FIG. 7 is a diagram illustrating the configuration of an imaging apparatus.

FIG. 8 is a diagram illustrating the configuration of an ADC.

### MODE FOR CARRYING OUT THE INVENTION

In the following, modes for carrying out the present technology (hereinafter referred to as embodiments) will be described. Note that the description will be made in the following order.

1. Configuration of a controller

2. Configuration of the controller in a first embodiment

3. Configuration of the controller in a second embodiment

4. Noise reduction

5. Example of application to an imaging apparatus

<Configuration of Controller>

The present technology can be employed to reduce settling time. Here, there will be described as an example a controller that mainly controls an auxiliary current in order to reduce the settling time.

The controller to which the present technology is applied can also be employed to reduce the settling time for a signal from a part of an imaging apparatus, specifically a comparison reference signal generating unit of a comparator, as described later. The imaging apparatus for example includes a part that uses an analog/digital converter (AD converter) to convert an analog pixel signal read from a pixel into digital data. Such an AD converter may be a so-called single-slope integrating or ramp signal comparing AD converter, for example.

The single-slope integrating AD converter that performs an AD conversion by comparing a reference signal includes a reference signal generation unit that generates a reference signal called a ramp wave which changes gradually from a predetermined initial voltage with a predetermined slope, a comparator that compares the reference signal with a pixel signal, and a counter that counts the time it takes for a magnitude relationship between the reference signal and the pixel signal to be reversed from the start of output of the reference signal by the reference signal generation unit (or the output of the predetermined initial value).

The following controller can be applied as a device that reduces the settling time for the part generating the reference signal.

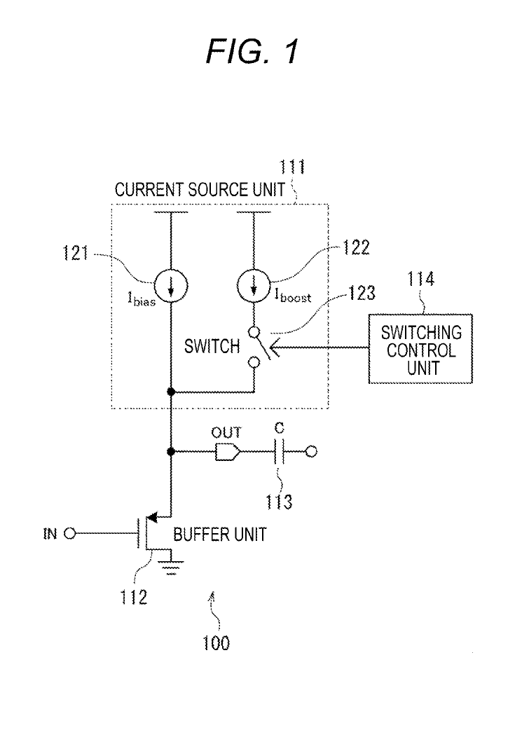

FIG. 1 is a diagram illustrating the configuration of an embodiment of a controller to which the present technology is applied. A controller 100 illustrated in FIG. 1 includes a current source unit 111. The current source unit 111 includes a bias current source 121, a boost current source 122 and a switch 123.

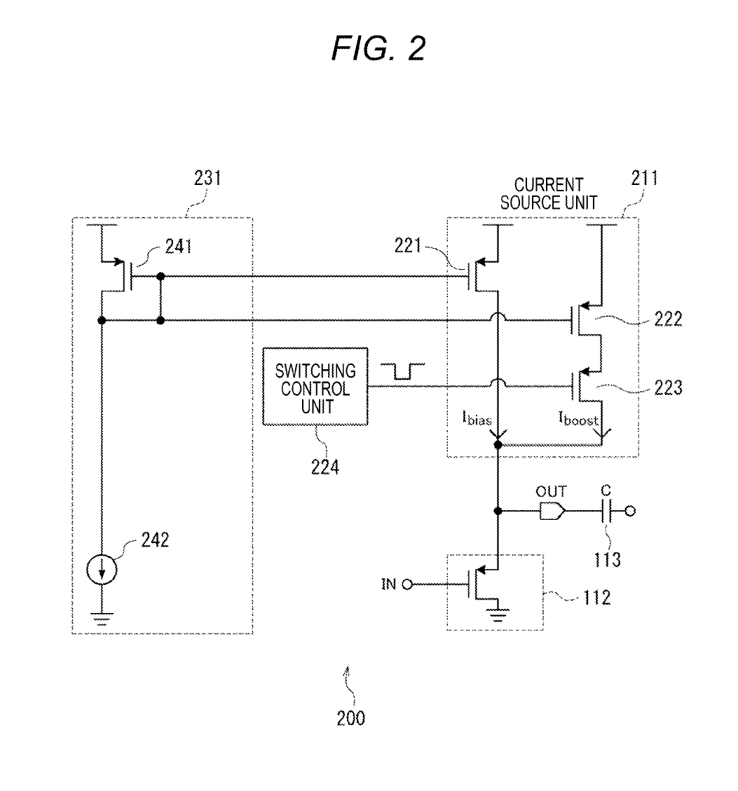

The controller 100 illustrated in FIG. 1 includes the bias current source 121 and the boost current source 122 to implement a settling improvement operation. While a specific configuration will be described with reference to FIG. 2, power consumption and the area can be reduced by employing a configuration with the current sources not using an amplifier or a resistor and the switch instead of a current source using an amplifier and a resistor.

In the controller 100, the bias current source 121 and the boost current source 122 are connected such that currents therefrom are supplied to an output voltage of a buffer unit 112. The current from the boost current source 122 is supplied when the switch 123 is closed, where opening and closing of the switch is controlled by a switching control unit 114.

Note that while the switching control unit 114 is included in this configuration, there may instead be employed a configuration in which the switching control unit 114 is not provided, the switch 123 and the switching control unit 114 are integrated, or the switching control unit 114 is included in the current source unit 111.

A capacitance 113 may be a load capacitance of a circuit (not shown) in a subsequent stage besides a parasitic capacitance dependent on a circuit, where the following description will be made assuming that the capacitance 113 includes such a load capacitance.

When the load capacitance or the parasitic capacitance is high (when a capacitance C is high), the time it takes for a bias current Ibias from the bias current source 121 to charge the capacitance C is increased to slow down settling of an output voltage OUT of the buffer unit 112.

In order to reduce the settling time, the switch 123 is closed at a time when one wishes to improve settling in response to a control signal from the switching control unit 114 so that a boost current Iboost is supplied from the boost current source 122. The boost current Iboost being supplied to the capacitance C allows the capacitance C to be charged by the boost current Iboost, whereby settling can be improved.

The controller 100 includes the bias current source 121 that generates an output signal according to an input signal and the boost current source 122 that supplies the current to charge the predetermined capacitance C as described above. The controller 100 further includes the switch 123 that controls the current from the boost current source 122 and the switching control unit 114 that controls opening and closing of the switch 123.

Moreover, an element included in the control unit 100 is formed of a transistor. With such configuration, the size reduction can be achieved, the settling can be improved, and the power consumption can be reduced as described above.

### Configuration of Controller According to First Embodiment

FIG. 2 is a diagram illustrating a specific circuit configuration of the controller 100 illustrated in FIG. 1. Similar reference signs are assigned to similar components in a controller 200 illustrated in FIG. 2 and the controller 100 illustrated in FIG. 1, and descriptions of such components will be omitted.

As with the current source unit 111 illustrated in FIG. 1, a current source unit 211 includes a bias current source 221, a boost current source 222 and a switch 223. The bias current source 221, the boost current source 222 and the switch 223 are each formed of a PMOS transistor.

The boost current source 222 is provided in the current source unit 211 to be able to supply a current for charging a capacitance C. Moreover, the switch 223 is provided to be able to control time to charge the capacitance C.

Here, each of the bias current source 221, the boost current source 222 and the switch 223 being formed of the PMOS transistor in the following description can also be formed of an NMOS transistor. Moreover, a buffer unit 112 being formed of a PMOS transistor in the following example can also be formed of an NMOS transistor.

Opening and closing of the switch 223 (turning on and off of the PMOS transistor) is controlled by a switching control unit 224. A control signal from the switching control unit 224 is input to a gate of the switch 223.

Note that the controller 200 can also be configured to perform control to detect input of an input signal by the switching control unit 224 and adjust the control signal according to the input.

According to the controller 200 illustrated in FIG. 2, the current through the current source unit 211 is controlled by a supply unit 231. That is, a bias in the current source unit 211 is generated by a current supply source 241 and a current source 242 of the supply unit 231.

According to such a configuration, a current proportional to a current flowing through one terminal can be extracted from another end. That is, in this case, a current proportional to a current flowing through the supply unit 231 can be extracted in the current source unit 211. Note that the current supply source 241 is formed of a PMOS transistor in this description but can also be formed of an NMOS transistor.

A bias current Ibias flowing through the bias current source 221 is determined by a ratio between the current supply source 241 (the PMOS transistor making up the current supply source 241) of the supply unit 231 and the bias current source 221 (the PMOS transistor making up the bias current source 221). Moreover, a boost current Iboost flowing through the boost current source 222 is also determined by a ratio between the current supply source 241 (the PMOS transistor making up the current supply source 241) of the supply unit 231 and the boost current source 222 (the PMOS transistor making up the boost current source 222).

According to the controller 200, a current proportional to the current flowing through the supply unit 231 flows as the bias current Ibias. The boost current Iboost is also proportional to the current flowing through the supply unit 231.

Each of the current source unit 211 and the supply unit 231 being components of the controller 200 does not include an amplifier. The amplifier has high current consumption in general and thus possibly hinders a reduction in power consumption. However, the controller 200 not including the amplifier can keep the power consumption down and achieve the reduction in the power consumption.

Moreover, each of the current source unit 211 and the supply unit 231 being the components of the controller 200 is formed of a transistor but does not include a resistor or a capacitor. The resistor and the capacitor are generally large in area, so that the controller 200 not including such a resistor or capacitor does not have a large area. That is, the controller 200 can be reduced in size.

Moreover, the controller 200 including the switch 223 can perform control to allow the boost current Iboost to flow not steadily but only when needed, whereby the amount of steady current consumption can be reduced. That is, with the switch 223 being provided, the controller can perform control to allow the boost current Iboost to flow only when the switch 223 is closed, whereby it is clear that the amount of current consumption can be reduced as compared to a device in which the boost current Iboost flows continuously.

In order to reduce the settling time, the controller 200 closes the switch 223 at a time when one wishes to improve settling in response to a control signal from the switching control unit 224 and allows the boost current Iboost to be supplied from the boost current source 222. The boost current Iboost being supplied to the capacitance C allows the capacitance C to be charged by the boost current Iboost, whereby settling can be improved.

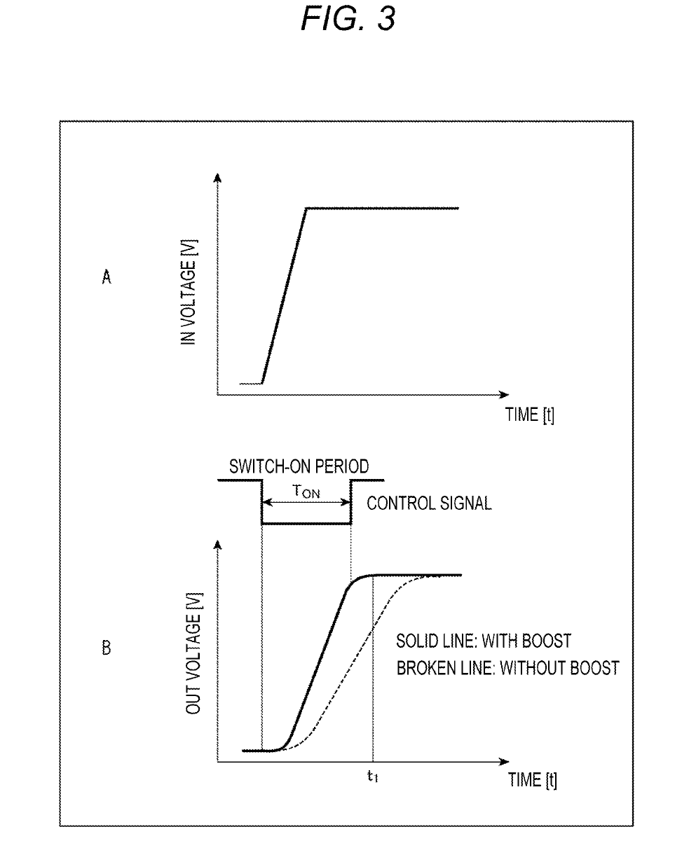

There will be described the reduction in the settling time that can be achieved by the controller 200. FIGS. 3A and 3B illustrate an example of a waveform at the time of a settling improvement operation performed by the controller 200. A of FIG. 3 is a graph of a voltage input to the controller 200 with a horizontal axis representing time and a vertical axis representing an input voltage (IN voltage). B of FIG. 3 is a graph of a voltage output from the controller 200 when the voltage as illustrated in A of FIG. 3 is input thereto, the graph including a horizontal axis representing time and a vertical axis representing an output voltage (OUT voltage).

In the graph illustrated in B of FIG. 3, a solid line represents a waveform of the output voltage with a boost while a broken line represents a waveform of the output voltage without a boost. Moreover, a waveform of the control signal output from the switching control unit 224 to the switch 223 (the signal supplied to the gate of the PMOS transistor making up the switch 223) is illustrated at the top of B of FIG. 3, in which TON indicates the time during which the switch 223 is closed.

In response to a change in the input voltage IN to the controller 200, the bias current flows first to charge the load capacitance or the parasitic capacitance (the capacitance 113) so that the larger the capacity of the capacitance 113, the longer the settling time of the output voltage OUT.

The broken line in B of FIG. 3 indicates a behavior when the settling is slow without the supply of the boost current. It is assumed that a circuit (not shown) in a subsequent stage starts an operation at time t1, for example. Without a boost, the output voltage OUT is not at a desired voltage level at time t1 so that the circuit in the subsequent stage may not be operated normally. It is thus required to increase the current and speed up the settling in order to avoid such a situation.

Accordingly, with the configuration where the boost current can be supplied as illustrated in FIG. 2, the output voltage OUT has the waveform as indicated by the solid line in B of FIG. 3 and reaches the desired voltage level at time t1, whereby the circuit in the subsequent stage can be operated normally.

The boost current Iboost flows only during the time TON during which the switch 223 is closed (the PMOS transistor making up the switch 223 is turned on). The time TON is adjusted by a control signal according to the size of the capacitance C to allow the bias current Ibias and the boost current Iboost to flow to the output voltage OUT, so that the charging time is sped up and that the settling time is improved.

Referring back to B of FIG. 3, the settling is finished before time t1 when the boost current is supplied as indicated by the solid line, in which case the circuit in the subsequent stage can be operated normally. That is, the settling time can be reduced according to the present technology.

Moreover, during the time TON, the switch 223 is closed to allow the boost current Iboost to flow, whereas the boost current Iboost does not flow outside the time TON so that the steady current outside the time TON is not increased even when the boost current source 222 is added in the configuration. The power consumption can be reduced as a result.

While the current source 242 in the supply unit 231 is a fixed current source in the controller 200 illustrated in FIG. 2, the current source can instead be a variable current source to enable fine current control. Moreover, as described above, the buffer unit 112, the transistor in the current source unit 211 and the transistor in the supply unit 231 can be formed of the PMOS transistors or the NMOS transistors, or a mixture of the PMOS and NMOS transistors.

### Configuration of Controller According to Second Embodiment

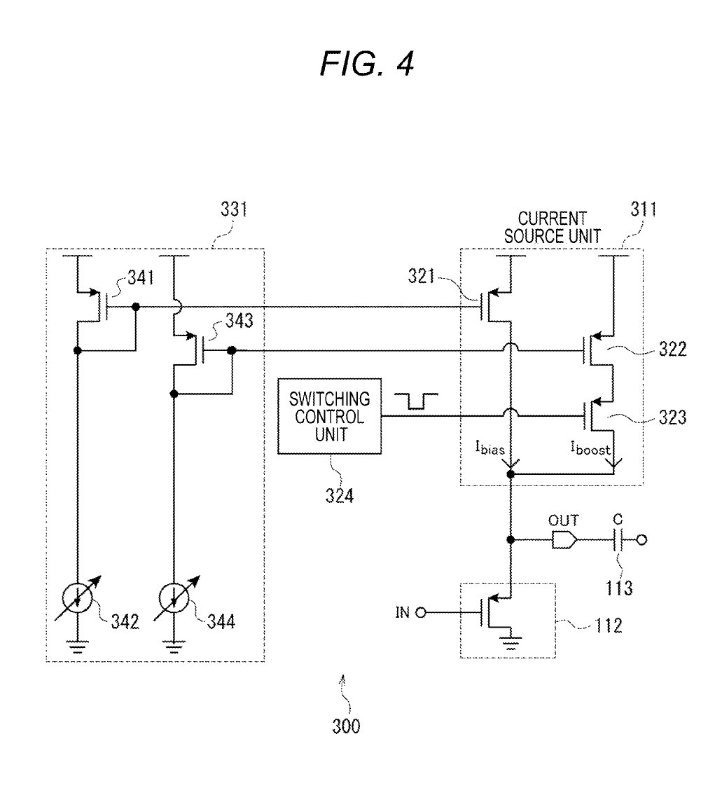

Next, a controller according to a second embodiment will be described. FIG. 4 is a diagram illustrating the configuration of a controller 300 according to the second embodiment.

The controller 300 illustrated in FIG. 4 is different from the controller 200 illustrated in FIG. 2 in that a second current supply unit 343 and a second current source 344 are added in a supply unit 331.

As with a current source unit 211 illustrated in FIG. 2, a current source unit 311 includes a bias current source 321, a boost current source 322 and a switch 323. The bias current source 321, the boost current source 322 and the switch 323 are each formed of a PMOS transistor.

The boost current source 322 is provided in the current source unit 311 to be able to supply a current for charging a capacitance C. Moreover, the switch 323 is provided to be able to control time to charge the capacitance C.

Opening and closing of the switch 323 (turning on and off of the PMOS transistor) is controlled by a switching control unit 324. A control signal from the switching control unit 324 is input to a gate of the switch 323.

According to the controller 300 illustrated in FIG. 4, the current through the current source unit 311 is controlled by the supply unit 331. A bias current Ibias of the bias current source 321 in the current source unit 311 is generated by a first current supply unit 341 and a first current source 342 in the supply unit 331. A boost current Iboost of the boost current source 322 in the current source unit 311 is generated by the second current supply unit 343 and the second current source 344 in the supply unit 331.

According to such a configuration, a current proportional to a current flowing through one terminal can be extracted from another end. That is, in this case, a current proportional to a current flowing through the supply unit 331 can be extracted in the current source unit 311.

The bias current Ibias flowing through the bias current source 321 is determined by a ratio between the first current supply unit 341 (the PMOS transistor making up the first current supply unit 341) of the supply unit 331 and the bias current source 321 (the PMOS transistor making up the bias current source 321). Moreover, the boost current Iboost flowing through the boost current source 322 is determined by a ratio between the second current supply unit 343 (the PMOS transistor making up the second current supply unit 343) of the supply unit 331 and the boost current source 322 (the PMOS transistor making up the boost current source 322).

Each of the current source unit 311 and the supply unit 331 being components of the controller 300 does not include an amplifier. The amplifier has high current consumption in general and thus possibly hinders a reduction in power consumption. However, the controller 300 not including the amplifier can keep the power consumption down and achieve the reduction in the power consumption.

Moreover, each of the current source unit 311 and the supply unit 331 being the components of the controller 300 is formed of a transistor but does not include a resistor or a capacitor. The resistor and the capacitor are generally large in area, so that the controller 300 not including such a resistor or capacitor does not have a large area. That is, the controller 300 can be reduced in size.

Moreover, the controller 300 including the switch 323 can perform control to allow the boost current Iboost to flow not steadily but only when needed, whereby the amount of steady current consumption can be reduced. That is, with the switch 323 being provided, the controller can perform control to allow the boost current Iboost to flow only when the switch 323 is closed, whereby it is clear that the amount of current consumption can be reduced as compared to a device in which the boost current Iboost flows continuously.

In order to reduce the settling time, the controller 300 closes the switch 323 at a time when one wishes to improve settling in response to a control signal from the switching control unit 324 and allows the boost current Iboost to be supplied from the boost current source 322. The boost current Iboost being supplied to the capacitance C allows the capacitance C to be charged by the boost current Iboost, whereby settling can be improved.

In the controller 300 illustrated in FIG. 4, a buffer unit 112, the transistor in the current source unit 311 and the transistor in the supply unit 331 can be formed of the PMOS transistors as illustrated in the aforementioned example, or can be formed of the NMOS transistors or a mixture of the PMOS and NMOS transistors.

In the controller 300 illustrated in FIG. 4, each of the first current source 342 and the second current source 344 in the supply unit 331 is a variable current source. The variable current source enables fine current control. Moreover, the first current source 342 and the second current source 344 in the controller 300 are provided independently. Such a configuration enables finer current control. The operation of the controller 300 will now be described.

In reducing the settling time, the controller 300 performs control to increase the boost current from the boost current source 322 without changing the bias current from the bias current source 321. In this case, the controller controls the bias current source 321 to output a steady current by controlling the current from the first current source 342 of the supply unit 331 to be constant.

Then when the settling time is to be reduced, the switch 323 is closed under control of the switching control unit 324 to allow the boost current Iboost to flow from the boost current source 322 and, as a result, the sum of the steady current Ibias and the boost current Iboost flows to the capacitance C.

It may also be adapted to allow the current to flow from the second current source 344 of the supply unit 331 only when the switch 323 is closed. The second current source 344 is provided independently from the first current source 342, so that the controller can perform control to stop the current from the second current source 344 while the current flows from the first current source 342. Moreover, the second current source 344 being the variable current source can output a required amount of current when needed.

Moreover, when the capacitance C is variable, the controller can perform control to increase the boost current Iboost from the boost current source 322 by increasing the current from the second current source 344 when the capacitance C is large, or perform control to decrease the boost current Iboost from the boost current source 322 by decreasing the current from the second current source 344 when the capacitance C is small.

Furthermore, when the boost current Iboost is supplied to the capacitance C, the controller may control the first current source 342 in the supply unit 331 such that the bias current Ibias from the bias current source 321 is increased as compared to when the boost current Iboost is not supplied to the capacitance C.

Such various controls can be implemented by providing the first current source 342 and the second current source 344, each being the variable current source, independently in the supply unit 331.

Note that while the first current source 342 and the second current source 344 in the supply unit 331 are the variable current sources in this case, the aforementioned controls can also be implemented when one of the current sources is a variable current source and the other current source is a fixed current source. Moreover, when the controller does not require fine control, the first current source 342 and the second current source 344 in the supply unit 331 can both be fixed current sources.

Furthermore, while the first current source 342 and the second current source 344 in the supply unit 331 are provided independently in the aforementioned example, the current sources can instead be provided as one current source. When the first current source 342 and the second current source 344 are provided as one current source, the flow of the boost current Iboost can also be controlled by opening and closing of the switch 323 so that the bias current Ibias and the boost current Iboost can be supplied to the capacitance C when the settling time is to be reduced.

The degree of flexibility in adjusting the boost current Iboost can thus be increased by the provision of the switch 323. That is, the controller 300 can have the increased flexibility in adjusting the boost current Iboost by the combined use of the second current supply unit 343 being the source of current for the boost current source 322 and the variable current source during the time TON during which the switch 323 is closed.

Note that the controller 300 can also perform control to detect input of an input signal by the switching control unit 324 and adjust the control signal according to the input.

As described above, the controller 300 can also achieve the reduction in the power consumption, the size, and the settling time.

<Noise Reduction>

Now, the controller 200 illustrated in FIG. 2 and the controller 300 illustrated in FIG. 4 each include the switch 223 (or the switch 323), the opening and closing of which may cause a switching noise.

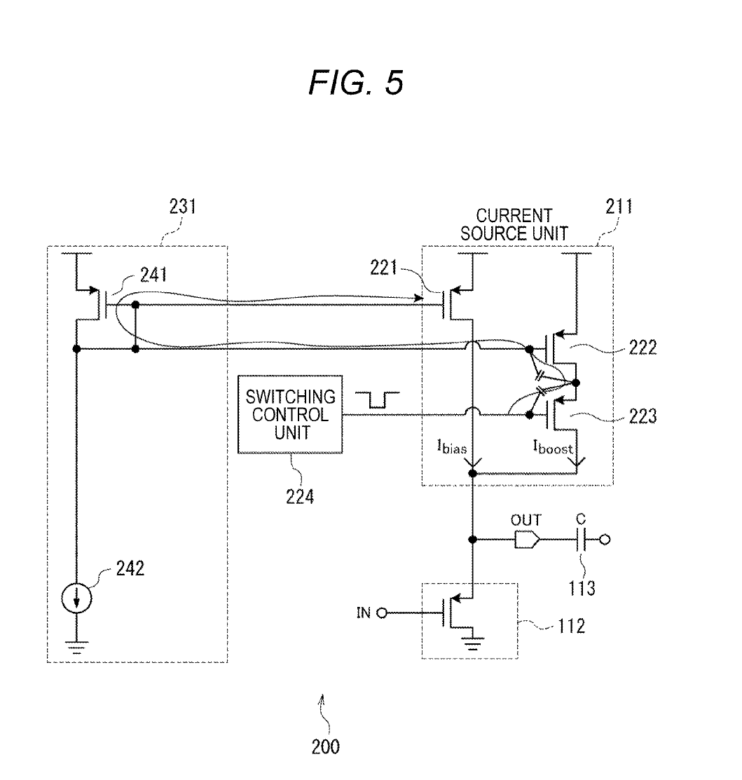

The noise generated in the controller 200 will be described with reference to FIG. 5. FIG. 5 is a diagram illustrating a path of propagation of the noise generated in the controller 200 illustrated in FIG. 2, the path being indicated by an arrow. As indicated by the arrow in FIG. 5, the switching noise generated at the time of switching of the switch 223 in the boost current source 222 possibly propagates to the current supply source 241 in the supply unit 231 via the parasitic capacitance between the gate and source of the switch 223 (PMOS transistor) and the parasitic capacitance between the drain and gate of the boost current source 222.

The switching noise may further propagate from the current supply source 241 to the gate of the bias current source 221.

The bias current Ibias fluctuates as the switching noise propagates to the bias current source 221, thereby possibly generating a noise in the output voltage OUT. The noise generated as a result of the propagation of such switching noise can be a problem in the application with a strict requirement on noise.

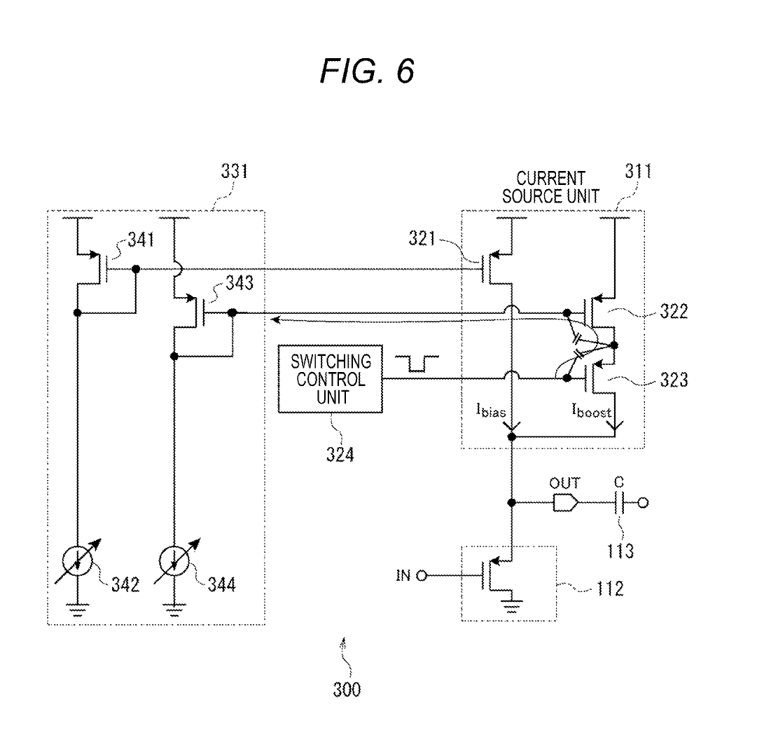

As described with reference to FIG. 6, the controller 300 can suppress the noise generated as a result of the propagation of such switching noise, so that the controller 300 may be employed in the application with a strict requirement on noise, while the controller 200 may be employed in the application without a strict requirement on noise.

The noise generated in the controller 300 will be described with reference to FIG. 6. FIG. 6 is a diagram illustrating a path of propagation of the noise generated in the controller 300 illustrated in FIG. 4, the path being indicated by an arrow. As indicated by the arrow in FIG. 6, the switching noise generated at the time of switching of the switch 323 in the boost current source 322 possibly propagates to the second current supply unit 343 in the supply unit 331 via the parasitic capacitance between the gate and source of the switch 323 (PMOS transistor) and the parasitic capacitance between the drain and gate of the boost current source 222.

As for the controller 300, the switching noise possibly propagates to the second current supply unit 343 in the supply unit 331. However, the second current supply unit 343 is provided independently from the first current supply unit 341 connected to the bias current source 321, whereby the switching noise does not propagate from the second current supply unit 343 to the first current supply unit 341. It is thus not possible for the switching noise to propagate from the first current supply unit 341 to the bias current source 321.

The controller 300 can thus suppress the noise generated by the propagation of the switching noise. Therefore, the controller 300 can be applied for use with a strict requirement on noise.

<Example of Application to Imaging Apparatus>

An application to an image sensor can have a strict requirement on noise. Here, there will be described an example in which the controller 300 is applied to the image sensor (imaging apparatus).

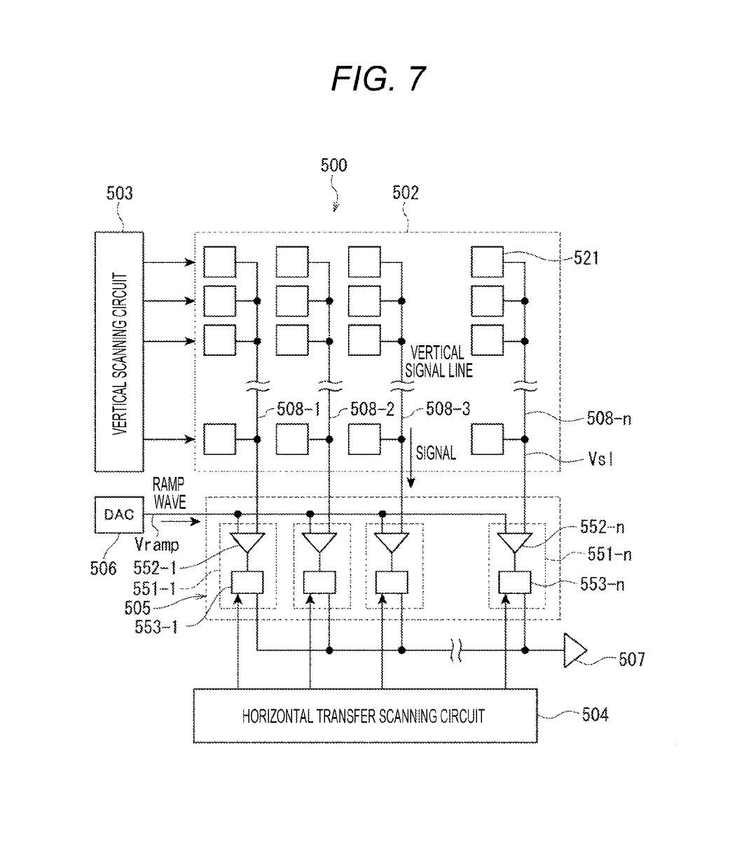

The controller 300 can be applied as a unit making up a part of an A/D conversion circuit (ADC) of the imaging apparatus, for example. FIG. 7 is a block diagram illustrating an example of the configuration of an imaging apparatus (CMOS image sensor) having a column parallel ADC.

An imaging apparatus 500 illustrated in FIG. 7 includes a pixel unit 502, a vertical scanning circuit 503, a horizontal transfer scanning circuit 504, and a column processing circuit group 505 made up of an ADC group. The imaging apparatus 500 further includes a digital-analog converter (DAC) 506 and an amplifier circuit 507. The pixel unit 502 is formed of unit pixels 521 each including a photodiode (photoelectric conversion element) and an in-pixel amplifier, where the unit pixels are arranged in a matrix pattern.

Column processing circuits 551-1 to 551-n forming the ADC in each column are arrayed in the column processing circuit group 505. The column processing circuits 551-1 to 551-n will be hereinafter simply noted as a column processing circuit 511 when the individual circuits need not be distinguished from one another. The other components will also be noted in a similar manner.

The column processing circuits 551-1 to 551-n include comparators 552-1 to 552-n, respectively, which compare a reference signal RAMP (reference voltage Vramp) being a ramp waveform obtained by a stepwise change of a reference signal generated by the DAC 506, with an analog signal obtained via corresponding vertical signal lines 508-1 to 508-n from the corresponding pixels for each row line.

Moreover, each column processing circuit 551 includes a counter latch 553 that counts the time of comparison by the comparator 552 and holds a result of the counting. The column processing circuit 551 has an n-bit digital signal conversion function and is arranged for each of the vertical signal lines (column lines) 508-1 to 508-n, thereby making up a column parallel ADC block. Output of each column processing circuit 551 is connected to a horizontal transfer line of a k-bit width, for example. Then, k units of the amplifier circuits 507 are arranged to correspond to the horizontal transfer lines.

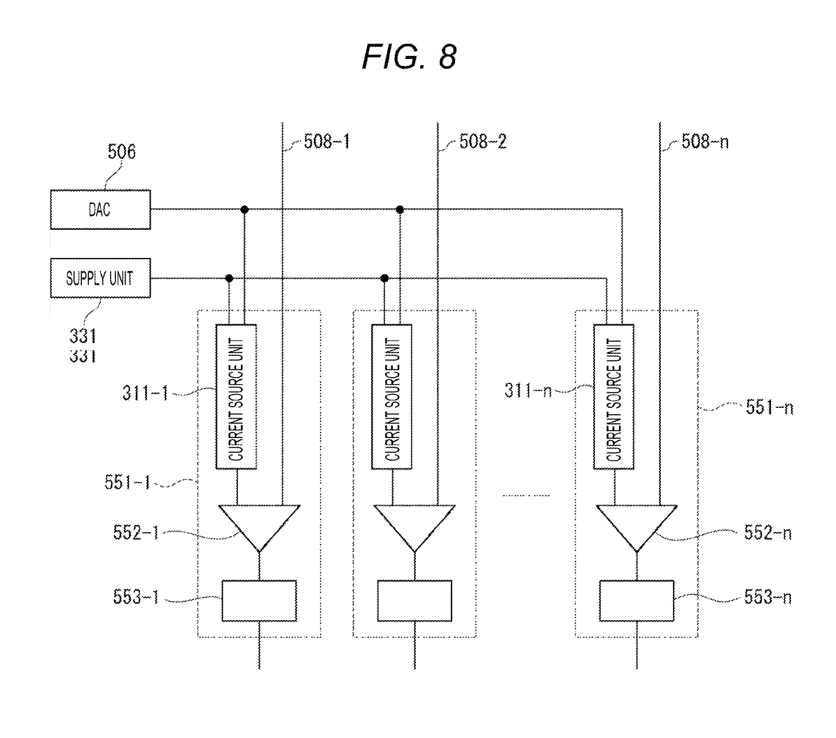

FIG. 8 is a block diagram of the ADC 551 in which the controller 300 is applied. The ADC 551 includes the comparator 552 and the counter latch 553 as described with reference to FIG. 7, where the signal from each pixel and the ramp wave from the DAC 506 are supplied to the comparator 552.

When the controller 300 is applied to the ADC 551 having such a configuration to reduce the settling time, the current source unit 311 can be provided first in each ADC 551. That is, as illustrated in FIG. 8, the current source unit 311 is provided between the DAC 506 and the comparator 552. With such a configuration, the ramp wave from the DAC 506 is supplied to the comparator 552 through the current source unit 311.

The comparator 552 receives input of the ramp wave from the current source unit 311 and the signal from the pixel. While the current source unit 311 is provided in each ADC 551 as described above, the supply unit 331 need not necessarily be provided in each ADC 551 but current source units 311-1 to 311-n can share one supply unit 331 as illustrated in FIG. 8.

The imaging apparatus 500 includes the plurality of ADCs 551, each of which includes the current source unit 311, whereby the plurality of current source units 311 is included. The current source unit 311 is configured to be able to contribute to the reduction in the size and power consumption as described above, so that the reduction in the size and power consumption of the imaging apparatus 500 is not hindered even when the plurality of current source units is provided.

In order for the ADC 551 to start a new AD conversion after completing an AD conversion, the converter requires time (so-called the settling time) to restore the reference signal (ramp wave) to an initial value. Although it is preferable to reduce the settling time in order to speed up AD conversion processing, the AD conversion may not be performed properly when the settling time is reduced without careful consideration to allow the new AD conversion to start before the reference signal is fully restored to the initial value.

However, the ADC 511 including the controller 300 as illustrated in FIG. 8 can reduce the settling time as well as prevent the start of the new AD conversion before the reference signal is fully restored to the initial value.

According to the imaging apparatus including the controller to which the present technology is applied, the settling time for the controller can be reduced so that the imaging apparatus can achieve higher speed and frame rate.

Note that the controller to which the present technology is applied is applied to the imaging apparatus in this case, but can also be applied to a device other than the imaging apparatus.

In this specification, a system refers to the entirety including a plurality of devices.

Note that the effects described herein are merely illustrated by way of example and not by way of limitation, where there may be other effects.

It should be noted that the embodiments of the present technology are not limited to the above described embodiments but can be modified in various ways without departing from the scope of the present technology.

Note that the present technology can also be embodied in the following configurations.

(1)

A controller including:

a first current source that generates an output signal corresponding to an input signal;

a second current source that supplies a current to charge a predetermined capacitance; and

a control unit that controls the current supplied from the second current source to the predetermined capacitance, where

the first current source and the second current source are each formed of a transistor.

(2)

The controller according to (1), further including a supply unit that supplies a current flowing to the first current source and the second current source, where

the current flowing to the first current source and the second current source is proportional to a current flowing in the supply unit.

(3)

The controller according to (1) or (2), where the control unit is a switch that is closed when settling time is to be reduced.

(4)

The controller according to (2) or (3), where

the supply unit includes a current source outputting a fixed current.

(5)

The controller according to (2) or (3), where

the supply unit includes a current source outputting a variable current.

(6)

The controller according to any of (2) to (5), where

the supply unit includes a first current supply unit that supplies a current to the first current source and a second current supply unit that supplies a current to the second current source.

(7)

The controller according to (6), where

the first current supply unit includes a first transistor and a first current generating source, while the second current supply unit includes a second transistor and a second current generating source.

(8)

The controller according to (7), where

the first current generating source and the second current generating source are provided independently.

(9)

The controller according to (7), where

the first current generating source and the second current generating source are each a current source outputting a variable current.

(10)

The controller according to (7), where

the first current generating source and the second current generating source are each a current source outputting a fixed current.

(11)

A control method of a controller including:

a first current source that generates an output signal corresponding to an input signal;

a second current source that supplies a current to charge a predetermined capacitance; and

a control unit that controls the current supplied from the second current source to the predetermined capacitance, where

the first current source and the second current source are each formed of a transistor, and

the method includes a step in which the control unit performs control to supply, to the predetermined capacitance, the current from the second current source in addition to a current from the first current source when settling time is to be reduced.

(12)

An AD converter including:

a comparator that compares a reference signal changing gradually from a predetermined initial voltage at a predetermined slope with a pixel signal;

a counter that counts time for a magnitude relationship between the reference signal and the pixel signal to be reversed from a start of input of the reference signal;

a first current source that uses the reference signal as an input signal and generates an output signal corresponding to the input signal;

a second current source that supplies a current besides a current from the first current source until the reference signal equals a predetermined value; and a control unit that controls a flow of the current from the second current source, where

the first current source and the second current source are each formed of a transistor.

(13)

An AD conversion method of an AD converter including:

a comparator that compares a reference signal changing gradually from a predetermined initial voltage at a predetermined slope with a pixel signal;

a counter that counts time for a magnitude relationship between the reference signal and the pixel signal to be reversed from a start of input of the reference signal;

a first current source that uses the reference signal as an input signal and generates an output signal corresponding to the input signal;

a second current source that supplies a current besides a current from the first current source until the reference signal equals a predetermined value; and

a control unit that controls a flow of the current from the second current source, where

the first current source and the second current source are each formed of a transistor, and

the method includes a step in which the control unit performs control to supply, to the predetermined capacitance, the current from the second current source in addition to the current from the first current source when settling time is to be reduced.

### REFERENCE SIGNS LIST

200 Controller
211 Current source unit
221 Bias current source
222 Boost current source
223 Switch
224 Switching control unit
231 Supply unit
241 Current supply source
242 Current source
300 Controller
311 Current source unit
321 Bias current source
322 Boost current source
323 Switch
324 Switching control unit
331 Supply unit
341 First current supply source
342 First current source
343 Second current supply source
344 Second current source

What is claimed is:

1. A controller comprising:
a first current source that generates an output signal corresponding to an input signal;
a second current source that supplies a current to charge a predetermined capacitance; and
a control unit that controls the current supplied from the second current source to the predetermined capacitance, wherein
the first current source and the second current source are each formed of a transistor.

2. The controller according to claim 1, further comprising
a supply unit that supplies a current flowing to the first current source and the second current source, wherein
the current flowing to the first current source and the second current source is proportional to a current flowing in the supply unit.

3. The controller according to claim 1, wherein
the control unit is a switch that is closed when settling time is to be reduced.

4. The controller according to claim 2, wherein
the supply unit further includes a current source outputting a fixed current.

5. The controller according to claim 2, wherein
the supply unit further includes a current source outputting a variable current.

6. The controller according to claim 2, wherein
the supply unit further includes a first current supply unit that supplies a current to the first current source and a second current supply unit that supplies a current to the second current source.

7. The controller according to claim 6, wherein
the first current supply unit further includes a first transistor and a first current generating source, while the second current supply unit further includes a second transistor and a second current generating source.

8. The controller according to claim 7, wherein
the first current generating source and the second current generating source are provided independently.

9. The controller according to claim 7, wherein
the first current generating source and the second current generating source are each a current source outputting a variable current.

10. The controller according to claim 7, wherein
the first current generating source and the second current generating source are each a current source outputting a fixed current.

11. A control method of a controller comprising:
a first current source that generates an output signal corresponding to an input signal;
a second current source that supplies a current to charge a predetermined capacitance; and
a control unit that controls the current supplied from the second current source to the predetermined capacitance, wherein
the first current source and the second current source are each formed of a transistor, and
the method includes a step in which the control unit performs control to supply, to the predetermined capacitance, the current from the second current source in addition to a current from the first current source when settling time is to be reduced.

12. An AD converter comprising:
a comparator that compares a reference signal changing gradually from a predetermined initial voltage at a predetermined slope with a pixel signal;
a counter that counts time for a magnitude relationship between the reference signal and the pixel signal to be reversed from a start of input of the reference signal;
a first current source that uses the reference signal as an input signal and generates an output signal corresponding to the input signal;
a second current source that supplies a current besides a current from the first current source until the reference signal equals a predetermined value; and
a control unit that controls a flow of the current from the second current source, wherein
the first current source and the second current source are each formed of a transistor.

13. An AD conversion method of an AD converter comprising:
a comparator that compares a reference signal changing gradually from a predetermined initial voltage at a predetermined slope with a pixel signal;
a counter that counts time for a magnitude relationship between the reference signal and the pixel signal to be reversed from a start of input of the reference signal;
a first current source that uses the reference signal as an input signal and generates an output signal corresponding to the input signal;
a second current source that supplies a current besides a current from the first current source until the reference signal equals a predetermined value; and
a control unit that controls a flow of the current from the second current source, wherein
the first current source and the second current source are each formed of a transistor, and
the method includes a step in which the control unit performs control to supply, to the predetermined capacitance, the current from the second current source in addition to the current from the first current source when settling time is to be reduced.
